(19) United States
(12) Patent Application Publication
(10) Pub. No.: US 2025/0218816 A1
(43) Pub. Date: Jul. 3, 2025

(54) APPARATUS OF PROCESSING A SUBSTRATE

(71) Applicant: Semes Co., Ltd, Cheonan-si (KR)

(72) Inventors: Cheol Yong SHIN, Yongin-si (KR); Jae Youl KIM, Yongin-si (KR); Sang Hoon KIM, Incheon (KR); Ho Jong HWANG, Hwaseong-si (KR); In Ki JUNG, Hwaseong-si (KR)

(73) Assignee: Semes Co., Ltd, Cheonan-si (KR)

(21) Appl. No.: 19/005,271

(22) Filed: Dec. 30, 2024

(30) Foreign Application Priority Data
Dec. 29, 2023 (KR) 10-2023-0197505

(51) Int. Cl. H01L 21/67; H01L 21/687

(52) U.S. Cl. CPC H01L 21/67057; H01L 21/68764

(57) ABSTRACT

The present invention relates to an apparatus of processing a substrate, in more detail, an apparatus of processing a substrate, the apparatus being able to separately discharge gas produced during substrate treatment. An object is to provide an apparatus of processing a substrate that can separately discharge gases simultaneously with treatment liquids and can provide uniform pressure in a plurality of exhaust baths.

### CROSS-REFERENCE TO RELATED APPLICATIONS

This application claims priority to and the benefit of Korean Patent Application No. 10-2023-0197505 filed in the Korean Intellectual Property Office on Dec. 29, 2023, the entire contents of which are incorporated herein by reference.

### TECHNICAL FIELD

The present invention relates to an apparatus of processing a substrate, in more detail, an apparatus of processing a substrate, the apparatus being able to separately discharge gases produced during substrate treatment.

### BACKGROUND ART

A semiconductor process includes a process of cleaning thin films, contaminants, particles, etc. on a substrate. The cleaning process is performed by putting a substrate on a spin chuck, rotating the spin chuck, and then supplying a treatment liquid to the top surface of the substrate in this state.

Various kinds of gases are produced, depending on the treatment liquids that are supplied to treat a substrate. According to an example, sulfuric acid gas is produced when the treatment liquid is a sulfuric acid solution, alkaline gas is produced when the treatment liquid is a Standard Clean-1 (SC-1) solution, and organic gas is produced when the treatment liquid is isopropyl alcohol (IPA).

In general, since gases are exhausted through one exhaust pipe, gages with various properties are mixed and exhausted. When gases are mixed, particles produced by an acid-base reaction accumulate in an exhaust path, so there is a problem that the particles may interfere with exhaust and it may fail to comply with gas emission regulations for preventing environmental pollution.

### SUMMARY OF THE INVENTION

An object of the present invention is to provide an apparatus of processing a substrate that can separately discharge gases simultaneously with treatment liquids.

Further, an object of the present invention is to provide an apparatus of processing a substrate that can prevent production of particles during exhaust of gases.

Further, an object of the present invention is to provide an apparatus of processing a substrate that can prevent environmental pollution by separately discharging gases.

Further, an object of the present invention is to provide an apparatus of processing a substrate that can provide uniform pressure in a plurality of exhaust ducts.

The objectives of the present invention are not limited thereto and other objectives not stated herein may be clearly understood by those skilled in the art from the following description.

An exemplary embodiment of the present invention, an apparatus of processing a substrate, comprising: a cup unit having a treatment space therein; a supporting unit supporting and rotating a substrate in the treatment space; a liquid supply unit provided to supply a treatment liquid selected from a plurality of treatment liquids to a substrate supported on the supporting unit; and an exhaust unit exhausting the treatment space, wherein the cup unit comprises: a first drain bath provided to surround an actuating shaft of the supporting unit and having a first recovery space to which a treatment is recovered; a first drain pipe coupled to the first drain bath to discharge the treatment liquid recovered in the first recovery space; a second drain bath provided to surround the first drain bath and having a second recovery space to which a treatment is recovered; a second drain pipe coupled to the second drain bath to discharge the treatment liquid recovered in the second recovery space; a first guide cup having a first inner surface guiding a treatment liquid, which is splashed from a substrate supported on the supporting unit, to the first drain bath; and a second guide cup provided to be surrounded by the first guide cup and having a second inner surface guiding a treatment liquid, which is splashed from a substrate supported on the supporting unit, to the second drain bath, wherein the exhaust unit comprises: a first exhaust bath disposed under the cup unit and having a first buffer space into which airflow flowing through a first passage, which is provided between an inner surface of the first guide cup and an outer surface of the second guide cup, flows; a first exhaust pipe connected to the first drain bath to discharge the airflow flowing in the first buffer space; a second exhaust bath disposed under the cup unit and having a second buffer space into which airflow flowing through a second passage, which is provided to be surrounded by the first exhaust bath when seen from above and is provided inside the second guide cup, flows; and a second exhaust pipe connected to the second exhaust bath to discharge the airflow flowing in the second buffer space, and wherein a first connection channel connecting the first passage and the first buffer space is positioned between the first drain bath and the second drain bath, and a second connection channel connecting the second passage and the second buffer space may be positioned inside the second drain bath.

According to an embodiment of the present invention, the first connection channel is provided as a ring-shaped slit surrounding the actuating shaft of the supporting unit or may be provided as a plurality of holes arranged to form a ring shape when seen from above.

According to an embodiment of the present invention, an arc-shaped guide plate is provided in the first buffer space, the guide plate is positioned higher than a height at which the first exhaust pipe is connected to the first exhaust bath, and the first exhaust pipe may be connected to the first exhaust bath in an area covered by the guide plate when seen from above.

According to an embodiment of the present invention, the farther from the point at which the first exhaust pipe may be connected to the first exhaust bath, the smaller the width of the guide plate when seen from above.

According to an embodiment of the present invention, a radial width of the first drain bath is constant in a longitudinal direction of the first drain bath when seen from above, and the width of the guide plate may be the same as the width of the first drain bath at the point at which the first exhaust pipe is connected to the first exhaust bath when seen from above.

According to an embodiment of the present invention, the second exhaust bath may be provided lower than the first exhaust bath.

According to an embodiment of the present invention, a line connecting the point at which the first exhaust pipe is connected to the first exhaust bath and the actuating shaft of the driving unit and a line connecting a point at which the second exhaust pipe is connected to the second exhaust bath and the actuating shaft of the driving unit may be provided not to overlap when seen from above.

According to an embodiment of the present invention, the apparatus may further include an elevation unit adjusting a relative height between the first guide cup and the second guide cup.

According to an embodiment of the present invention, when the first guide cup or the second guide cup is moved up, an outer wall of the first drain bath or an outer wall of the second drain bath extends farther than an inner wall of the first drain bath or an inner wall of the second drain bath such that a lower end of the first guide cup or the second guide cup may be maintained in contact with the outer wall of the first drain bath or the outer wall of the second drain bath.

According to an embodiment of the present invention, the apparatus may further include a gas-liquid separator plate protruding from an outer surface of the second guide cup, wherein the outer surface of the second guide cup is positioned inside further than an inner wall of the first drain bath when seen from above, and the gas-liquid separator plate extends downward into the first recovery space and may be spaced apart from the inner wall of the first drain bath.

According to an embodiment of the present invention, the cup unit further comprises a third guide cup provided to be surrounded by the second guide cup, and the second passage may be formed between an inner surface of the second guide cup and an outer surface of the third guide cup.

An exemplary embodiment of the present invention, an apparatus of processing a substrate, comprising: a cup unit having a treatment space therein; a supporting unit supporting and rotating a substrate in the treatment space; a liquid supply unit provided to supply a treatment liquid selected from a plurality of treatment liquids to a substrate supported on the supporting unit; and an exhaust unit exhausting the treatment space, wherein the cup unit comprises: a recovery bath recovering the treatment liquid; and a guide cup guiding the treatment liquid to the recovery bath, the recovery bath provides a recovery space, a passage through which gas is exhausted is formed further inside than the recovery bath, the exhaust unit comprises an exhaust bath disposed under the cup unit and provided in a ring shape along the passage, and an exhaust pipe connected to the exhaust bath, the exhaust bath has a buffer space therein, and an arc-shaped guide plate may be provided in the buffer space.

According to an embodiment of the present invention, the guide plate is positioned higher than a height at which the exhaust pipe is connected to the exhaust bath, and the exhaust pipe may be connected to the exhaust bath in an area covered by the guide plate when seen from above.

According to an embodiment of the present invention, the exhaust pipe may be connected to the exhaust bath at a center of the area covered by the guide plate when seen from above.

According to an embodiment of the present invention, the farther from the point at which the first exhaust pipe may be connected to the first exhaust bath, the smaller the width of the guide plate when seen from above.

According to an embodiment of the present invention, a radial width of the drain bath is constant in a longitudinal direction of the drain bath when seen from above, and the width of the guide plate is the same as the width of the drain bath at the point at which the exhaust pipe may be connected to the exhaust bath when seen from above.

An exemplary embodiment of the present invention, an apparatus of processing a substrate, comprising: a cup unit having a treatment space therein; a supporting unit supporting and rotating a substrate in the treatment space; a liquid supply unit provided to supply a treatment liquid selected from a plurality of treatment liquids to a substrate supported on the supporting unit; an elevation unit adjusting a relative height between the cup unit and the supporting unit; and an exhaust unit exhausting the treatment space, wherein the cup unit comprises: a first drain bath provided to surround an actuating shaft of the supporting unit and having a first recovery space to which a treatment is recovered; a first drain pipe coupled to the first drain bath to discharge the treatment liquid recovered in the first recovery space; a second drain bath provided to surround the first drain bath and having a second recovery space to which a treatment is recovered; a second drain pipe coupled to the second drain bath to discharge the treatment liquid recovered in the second recovery space; a first guide cup having a first inner surface guiding a treatment liquid, which is splashed from a substrate supported on the supporting unit, to the first drain bath; and a second guide cup provided to be surrounded by the first guide cup and having a second inner surface guiding a treatment liquid, which is splashed from a substrate supported on the supporting unit, to the second drain bath, the elevation unit adjusts a relative height between the first guide cup and the second guide cup, when the first guide cup or the second guide cup is moved up, an outer wall of the first drain bath or an outer wall of the second drain bath extends farther than an inner wall of the first drain bath or an inner wall of the second drain bath such that a lower end of the first guide cup or the second guide cup is maintained in contact with the outer wall of the first drain bath or the outer wall of the second drain bath, the exhaust unit comprises: a first exhaust bath disposed under the cup unit and having a first buffer space into which airflow flowing through a first passage, which is provided between an inner surface of the first guide cup and an outer surface of the second guide cup, flows; a first exhaust pipe connected to the first drain bath to discharge the airflow flowing in the first buffer space; a second exhaust bath disposed under the cup unit and having a second buffer space into which airflow flowing through a second passage, which is provided to be surrounded by the first exhaust bath when seen from above and is provided inside the second guide cup, flows; and a second exhaust pipe connected to the second exhaust bath to discharge the airflow flowing in the second buffer space, a first connection channel connecting the first passage and the first buffer space is positioned between the first drain bath and the second drain bath, and a second connection channel connecting the second passage and the second buffer space is positioned inside the second drain bath, an arc-shaped guide plate may be provided in the first buffer space, the first exhaust pipe is connected to the first exhaust bath at the center of the area covered by the guide plate when seen from above, the guide plate is positioned higher than a height at which the first exhaust pipe is connected to the first exhaust bath, and the farther from the point at which the first exhaust pipe is connected to the first exhaust bath, the smaller the width of the guide plate when seen from above.

According to an embodiment of the present invention, a radial width of the first drain bath is constant in a longitudinal direction of the first drain bath when seen from above, and the width of the guide plate may be the same as the width of the first drain bath at the point at which the first exhaust pipe is connected to the first exhaust bath when seen from above.

According to an embodiment of the present invention, the second exhaust bath is provided lower than the first exhaust bath, and a line connecting the point at which the first exhaust pipe is connected to the first exhaust bath and the actuating shaft of the driving unit and a line connecting a point at which the second exhaust pipe is connected to the second exhaust bath and the actuating shaft of the driving unit may be provided not to overlap when seen from above.

According to an embodiment of the present invention, it is possible to separately discharge gases with treatment liquids.

Further, according to an embodiment of the present invention, it is possible to prevent production of particles during exhaust of gas.

Further, according to an embodiment of the present invention, it is possible to prevent environmental pollution by separately discharging gases.

Further, according to an embodiment of the present invention, it is possible to provide uniform pressure in a plurality of exhaust ducts.

Effects of the present invention are not limited to those described above and effects not stated above will be clearly understood to those skilled in the art from the specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. Various dimensions in the drawing may be exaggerated for clarity in the accompanying drawings.

FIG. 1 is a plan view schematically showing an apparatus of processing a substrate according to an embodiment of the present invention.

FIG. 2 is a view showing the liquid treatment chamber of FIG. 1 when seen from above.

FIG. 3 is a view showing the liquid treatment chamber of FIG. 1 when seen from below.

FIG. 4 is a view schematically showing a cross-section of the liquid treatment chamber of FIG. 1.

FIG. 5 is an enlarged view of the portion A of FIG. 4.

FIG. 6 is a view schematically showing an example of an exhaust unit.

FIG. 7 is a view showing the exhaust unit when seen from below.

FIG. 8 is a view showing that guide plates have been provided in a buffer space when seen from above.

FIG. 9 to FIG. 11 are views showing treatment of a substrate when a guide cup has been moved up by an elevation unit.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

A wafer is exemplarily described as a target to be processed in this embodiment. However, the technical spirit of the present invention can be applied even to apparatuses that are used to treat other kinds of substrates in addition to a wafer as a treatment target.

Embodiments of the present invention are described hereafter in detail with reference to the accompanying drawings.

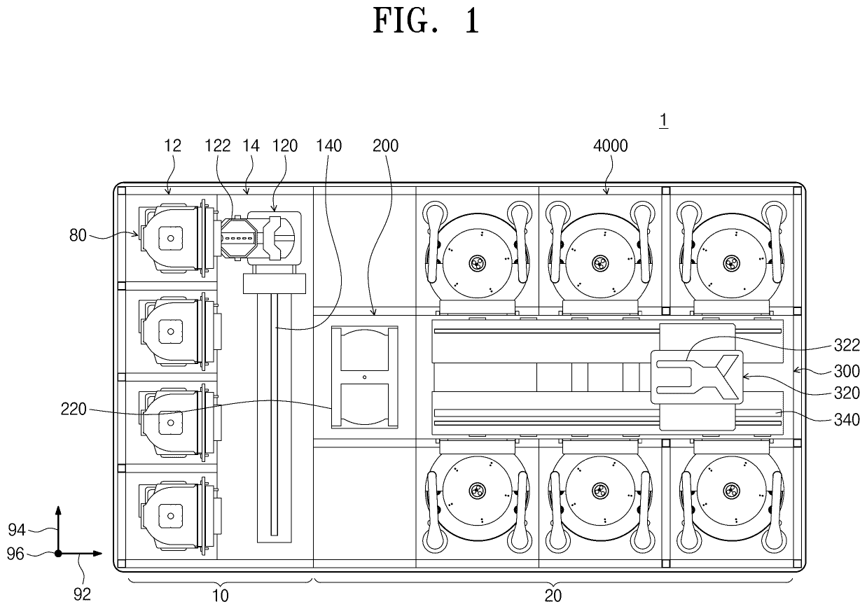

FIG. 1 is a plan view schematically showing an apparatus of processing a substrate according to an embodiment of the present invention.

Referring to FIG. 1, an apparatus of processing a substrate includes an index module 10, a treatment module 20, and a control unit 30. According to an embodiment, the index module 10 and the treatment module 20 are disposed in one direction. Hereafter, the direction in which the index module 10 and the treatment module 20 are arranged is referred to as a first direction 92, a direction perpendicular to the first direction 92 when seen from above is referred to as a second direction 94, and a direction perpendicular to both of the first direction 92 and the second direction 94 is referred to as a third direction 96.

The index module 10 transfers substrates W to the treatment module 20 from containers 80 accommodating the substrates W and puts the substrates W treated at the treatment module 20 into the containers 80. The longitudinal direction of the index module 10 is provided in the second direction 94. The index module 10 has a loadport 12 and an index frame 14. The loadport 12 is positioned at the opposite side to the treatment module 20 with the index frame 14 therebetween. The containers 80 accommodating substrates W are placed in the loadport 12. The load port 12 may be provided in multiple instances and the plurality of load ports 12 may be disposed in the second direction 94.

The container 80 may be a container for sealing such as a Front Open Unified Pod (FOUP). The container 80 may be placed in the loadport 12 by a worker or a conveying device (not shown) such as an overhead transfer, an overhead conveyor, or an automatic guided vehicle.

An index robot 120 is provided at the index frame 14. A guide rail 140 of which the longitudinal direction is provided in the second direction 94 is provided in the index frame 14 and the index robot 120 may be provided to be movable on the guide rail 140. The index robot 120 includes a hand 122 on which substrates W are placed and the hand 122 may be provided to be able to move forward and backward, rotate about the third direction 96, and move in the third direction 96. The hand 122 may be provided in multiple instances to be spaced apart from each other in the up-down direction and the hands 122 can move forward and backward independently from each other.

The treatment module 20 includes a buffer unit 200, a transfer chamber 300, and a treatment chamber 400. The buffer unit 200 provides a space in which substrates W that are loaded into the treatment module 20 and substrates W that are unloaded from the treatment module 20 temporarily stay. The treatment chamber 400 performs a treatment process of performing liquid treatment on substrates W by supplying liquid onto the substrates W. The transfer chamber 300 transfers substrates W between the buffer unit 200 and the liquid treatment chamber 400.

The longitudinal direction of the transfer chamber 300 may be provided in the first direction 92. The buffer unit 200 may be disposed between the index module 10 and the transfer chamber 300. The liquid treatment chamber 400 is provided in multiple instances and may be disposed on a side of the transfer chamber 300. The liquid treatment chamber 400 and the transfer chamber 300 may be disposed in the second direction 94. The buffer unit 200 may be positioned at an end of the transfer chamber 300.

According to an example, the liquid treatment chambers 400 may be disposed at both sides of the transfer chamber 300. The liquid treatment chambers 400 may be provided in an array of A×B (A and B are each a natural number of 1 or more) in the first direction 92 and the third direction 96, respectively, at each of both sides of the transfer chamber 300.

The transfer chamber 300 has a transfer robot 320. A guide rail 340 of which the longitudinal direction is provided in the first direction 92 is provided in the transfer chamber 300 and the transfer robot 320 may be provided to be movable on the guide rail 340. The transfer robot 320 includes a hand 322 on which substrates W are placed and the hand 322 may be provided to be able to move forward and backward, rotate about the third direction 96, and move in the third direction 96. The hand 322 may be provided in multiple instances to be spaced apart from each other in the up-down direction and the hands 322 can move forward and backward independently from each other.

The buffer unit 200 has a plurality of buffers 220 on which substrates W are placed. The buffers 220 may be disposed to be spaced apart from each other in the third direction 96. The buffer unit 200 is open on the front face and the rear face. The front face is a surface that faces the index module 10 and the rear face is a surface that faces the transfer chamber 300. The index robot 120 can approach the buffer unit 200 through the front face and the transfer robot 320 can approach the buffer unit 200 through the rear face.

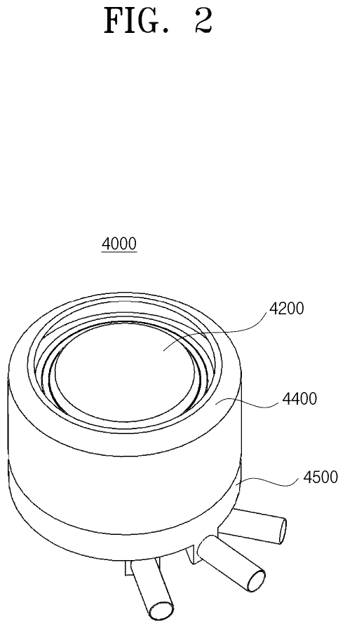

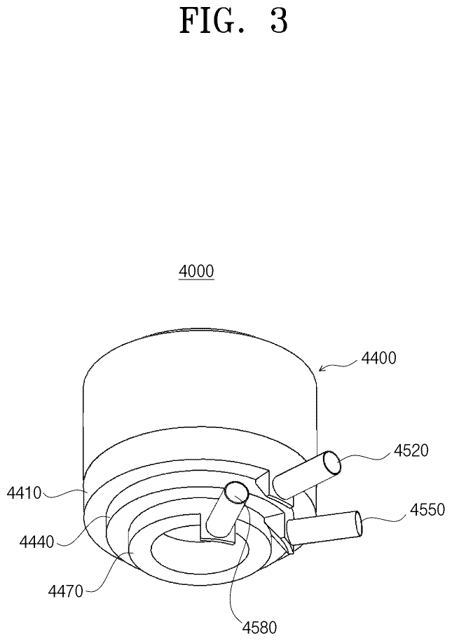

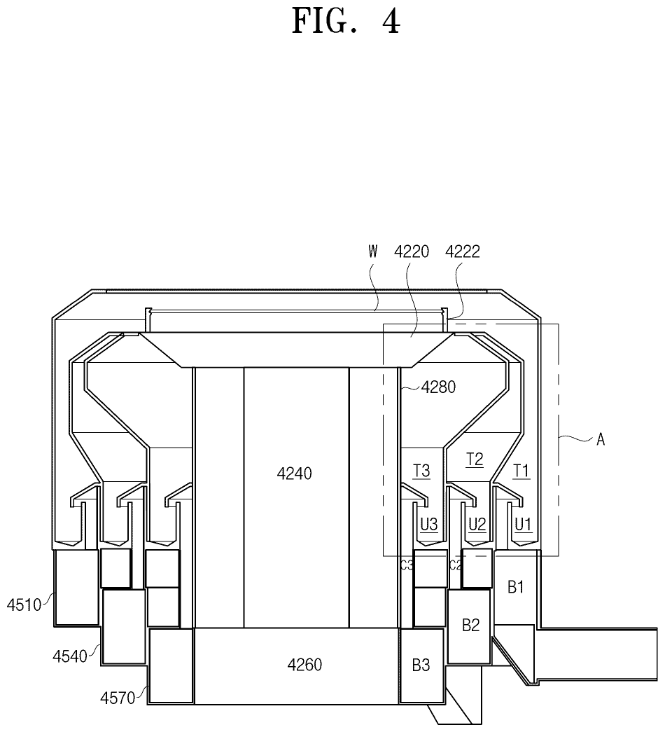

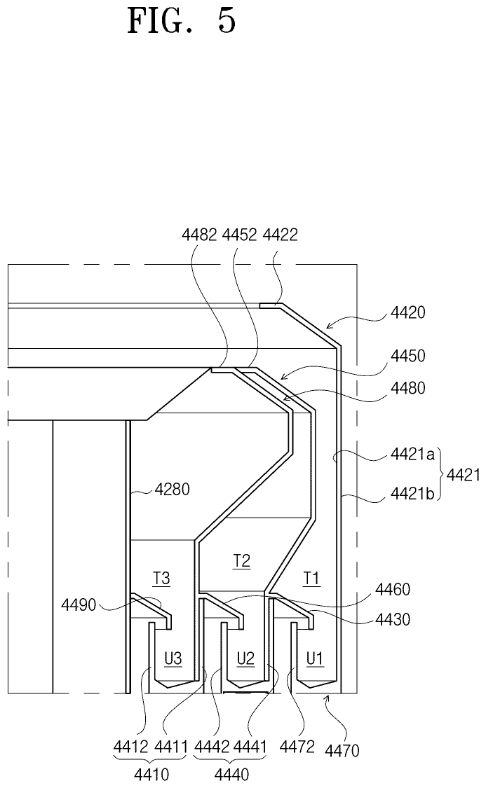

FIG. 2 is a view showing the liquid treatment chamber of FIG. 1 when seen from above, FIG. 3 is a view showing the liquid treatment chamber of FIG. 1 when seen from below, FIG. 4 is a view schematically showing a cross-section of the liquid treatment chamber of FIG. 1, and FIG. 5 is an enlarged view of the portion A of FIG. 4.

Referring to FIG. 2 to FIG. 5, a liquid treatment chamber 4000 includes a housing 4100, a supporting unit 4200, a liquid supply unit 4300, a cup unit 4400, an exhaust unit 4500, an elevation unit 4600, and a control unit.

The housing 4100 is provided substantially in a rectangular prism shape. The housing provides an internal space. Components to be described below may be disposed in the housing 4100. An opening (not shown) that is provided as a passage for substrates W may be formed on a side of the housing 4100.

The supporting unit 4200 has a supporting plate 4220, an actuating shaft 4240, an actuator 4260, and a supporting frame 4280. The upper surface of the supporting plate 4220 is provided substantially in a circular shape and may have a diameter larger than substrates W. Supporting pins 4221 supporting the rear surface of a substrate W is provided at the center portion of the supporting plate 4220 and are provided such that the upper ends thereof protrude from the supporting plate 4220 to space a substrate W a predetermined distance from the supporting plate 4220. Chuck pins 4222 are provided on the edge portion of the supporting plate 4220. The chuck pins 4222 protrude upward from the supporting plate 4200 and support the side of a substrate W to prevent the substrate W from separating from the supporting unit 4220 when the substrate W is rotated. The actuating shaft 4240 is connected to the center of the underside of the substrate W. The supporting plate 4220 can be rotated by rotation of the actuating shaft 4240. The actuator 4260 may be disposed under the actuating shaft 4240. The actuator 4260 rotates the actuating shaft 4240. The supporting frame 4280 may be provided to surround the outer sides of the actuating shaft 4240 and the actuator 4260. The supporting frame 4280 may be provided as a vertical wall. The supporting frame 4280 is provided independently from rotation of the actuating shaft 4240. The supporting frame 4280 is provided to prevent contamination of the actuating shaft 4240 and the actuator 4260 due to treatment liquids or gases.

The liquid supply unit 4300 includes a first nozzle 4320 and a second nozzle 4340. The first nozzle 4320 supplies a treatment liquid to substrates W. The treatment liquid may be a liquid at a higher temperature than the room temperature. According to an example, the treatment liquid may be a phosphoric acid solution. The phosphoric acid solution may be a mixture of phosphoric acid and water. Selectively, the phosphoric acid solution may further contain other substances. For example, the other substance may be silicon. The second nozzle 4340 supplies water onto substrates W. The water may be pure water or deionized water. The first nozzle 4320 and the second nozzle 4340 are supported by different arms 4310 and the arms 4310 can be independently moved. Selectively, the first nozzle 4320 and the second nozzle 4340 may be mounted on the same arm and moved simultaneously.

The cup unit 4400 has a treatment space with an open top and substrates W are liquid-treated in the treatment space. The relative height between the cup unit 4400 and the supporting unit 4200 is adjusted by the elevation unit 4500. The cup unit 4400 may include a plurality of drain baths, a plurality of guide cups, a plurality of gas-liquid separator plates, and a plurality of drain pipes.

According to an example, the cup unit 4400 has three drain baths 4410, 4440, and 4470. The drain baths 4410, 4440, and 4470 each have a recovery space for recovering liquid used to treat a substrate. The drain baths 4410, 4440, and 4470 has a shape with an open top. The drain baths 4410, 4440, and 4470 are each provided in a ring shape surrounding the supporting unit 4400. The drain baths 4410, 4440, and 4470 has a shape with an open top. The cross-section of the drain baths 4410, 4440, and 4470 in the third direction 96 may be a U-shape. The radial widths of the drain baths 4410, 4440, and 4470 are the same in the longitudinal direction of the drain baths 4410, 4440, and 4470. The drain baths 4410, 4440, and 4470 are provided to be spaced apart from each other. The drain baths 4410, 4440, and 4470 are provided at the same height. A first drain bath 4410 is provided to surround the actuating shaft 4470. A second drain bath 4440 is provided to be surrounded by the first drain bath 4410. A third drain bath 4470 is provided to be surrounded by the second drain bath 4440. A third drain bath 4470 is provided to surround the actuating shaft 4240. The drain baths 4410, 4440, and 4470 include inner walls 4412, 4442, and 4472 relatively adjacent to the actuating shaft 4240 and outer walls 4411, 4441, and 4471 facing the inner walls. The outer walls 4411, 4441, and 4471 and the inner walls 4412, 4442, and 4472 are combined, respectively, thereby forming recovery spaces U1, U2, and U3. The outer walls 4411, 4441, and 4471 have a length that is larger in the third direction 96 than the length of the inner walls 4412, 4442, and 4472. The length of the outer walls 4411, 4441, and 4471 may be a length that prevents separation of the guide cups 4420, 4450, and 4480 from the drain baths 4410, 4440, and 4470 even though the guide cups 4450 and 4480 are moved up.

According to an example, the cup unit 4400 has three guide cups 4420, 4450, and 4480. The guide cups 4420, 4450, and 4480 are positioned over the drain baths 4410, 4440, and 4470, respectively. The guide cups 4420, 4450, and 4480 are combined with the drain baths 4410, 4440, and 4470, respectively. The guide cups 4420, 4450, and 4480 guide a treatment liquid splashed from a substrate W to the drain baths 4410, 4440, and 4470. The guide cups 4420, 4450, and 4480 have a shape with open top and bottom. The guide cups 4420, 4450, and 4480 have side walls 4421, 4451, and 4481, respectively. A treatment liquid splashed from a substrate W can be recovered to the drain baths 4410, 4440, and 4470 along inner surfaces 4421a, 4451a, and 4481a of the side walls 4421, 4451, and 4481. The lengths of a second side wall 4451 and a third side wall 4481 in the third direction 96 are the same. The length of a first side wall 4421 in the third direction 96 is larger than those of the second side wall 4451 and the third side wall 4481. The length of the first side wall 4421 in the third direction 96 is provided such that the heights of upper walls 4423, 4453, and 4483 are the same when the second side wall 4451 and the third side wall 4481 are moved up. The upper walls 4423, 4453, and 4483 are formed by extending inward from the upper ends of the side walls 4421, 4451, and 4481. The upper walls 4423, 4453, and 4483 may be horizontally provided. A first upper wall 4423 may extend to be adjacent to a second upper wall 4453. The second upper wall 4453 may extend to be adjacent to a third upper wall 4483. A third upper wall 4483 may extend to be adjacent to the supporting frame 4280. The upper walls 4423, 4453, and 4483 may be provided not to overlap when seen from above. The side walls 442a, 445a, and 4481 of the guide cups are coupled to the outer walls 441a, 444a, and 4471 of the drain baths. The outer surfaces of the side walls 442a, 445a, and 4481 of the guide cups are provided to be adjacent to the inner surfaces of the outer walls 441a, 444a, and 4471. Further, the outer wall 4411 of the first drain bath may be provided integrally with the side wall 4421 of the first guide cup. The drain pipes 4413, 4443, and 4473 are connected to the drain baths 4410, 4440, and 4470, respectively. The drain pipes 4413, 4443, and 4473 are connected to the recovery spaces U1, U2, and U3, respectively. The drain pipes 4413, 4443, and 4473 discharge liquid treatments separately recovered in the recovery spaces U1, U2, and U3, respectively, to the outside.

The guide cups 4420, 4450, and 4480 and the supporting frame 4280 are combined thereby forming passages T1, T2, and T3 through which gases pass. The inner surface 4421a of the first guide cup and the outer surface 4451b of the second guide cup are combined with each other, thereby providing a first passage T1 through which a gas is exhausted. The inner surface 4451a of the second guide cup and the outer surface 4481b of the third guide cup are combined with each other, thereby providing a second passage T2 through which a gas is exhausted. The inner surface 4481a of the third guide cup and the outer surface 4281 of the supporting frame 4280 are combined with each other, thereby providing a third passage T3 through which a gas is exhausted.

According to an example, the cup unit 4400 has three gas-liquid separator plates 4430, 4460, and 4490. The gas-liquid separator plates 4430, 4460, and 4490 are provided in a ring shape. The gas-liquid separator plates 4430, 4460, and 4490 are provided in the passages T1, T2, and T3. A first gas-liquid separator plate 4430 has a shape protruding from the outer surface 4451b of the second side wall 4451. The first gas-liquid separator plate 4430 can extend to the first recovery space U1. A second gas-liquid separator plate 4460 has a shape protruding from the outer surface 4481b of the third side wall 4481. The second gas-liquid separator plate 4460 can extend to the second recovery space U2. A third gas-liquid separator plate 4490 has a shape protruding from the outer surface 4281 of the supporting frame. The third gas-liquid separator plate 4490 can extend to the third recovery space U3.

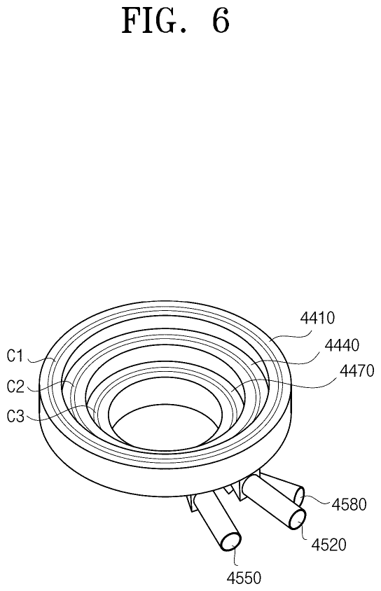

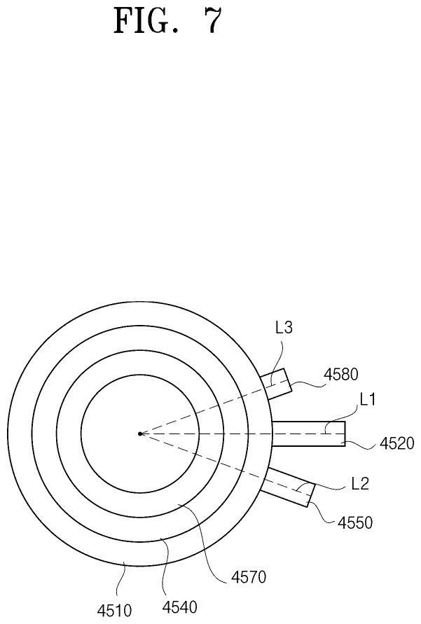

FIG. 6 is a view schematically showing an example of an exhaust unit and FIG. 7 is a view showing the exhaust unit when seen from below.

The exhaust unit 4500 exhausts the inside of the cup unit 4400. The exhaust unit 4500 is disposed under the cup unit 4400. The exhaust unit 4500 includes a plurality of exhaust baths and a plurality of exhaust pipes. According to an example, the exhaust baths and the exhaust pipes each may be provided in three.

The exhaust baths 4510, 4440, and 4470 provide paths for exhausting gas produced in the cup unit 4500. The exhaust baths 4510, 4440, and 4470 have buffer spaces B1, B2, and B3, respectively. Further, the exhaust baths 4510, 4440, and 4470 are connected with the passages T1, T2, and T3, respectively. Connection channels C1, C2, and C3 are provided between the exhaust baths 4510, 4440, and 4470 and the passages T1, T2, and T3, respectively.

The connection channels C1, C2, and C3 may be provided as ring-shaped slits surrounding the actuating shaft 4240 when seen from above. Further, the connection channels C1, C2, and C3 may be provided as a plurality of holes arranged to from a ring shape. A first connection channel C1 is positioned between the first drain bath 4510 and the second drain bath 4540. A second connection channel C2 is positioned between the second drain bath 4540 and the third drain bath 4570. A third connection channel C3 is positioned between the third drain bath 4570 and the supporting frame 4280.

The drain pipes 4520, 4550, and 4580 are connected to the exhaust baths 4510, 4440, and 4470, respectively. The exhaust pipes 4520, 4550, and 4580 have buffer spaces B1, B2, and B3, respectively. The joints where the exhaust pipes 4520, 4550, and 4580 are connected to the exhaust baths 4510, 4440, and 4470, respectively, are defined as V1, V2, and V3.

The exhaust pipes 4520, 4550, and 4580 may be provided not to overlap each other when seen from above. Lines L1, L2, and L3 connecting the joints V1, V2, and V3 and the actuating shaft 4240 may be provided not to overlap each other.

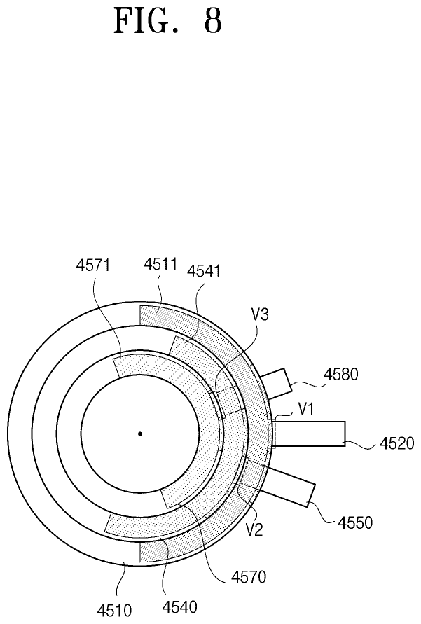

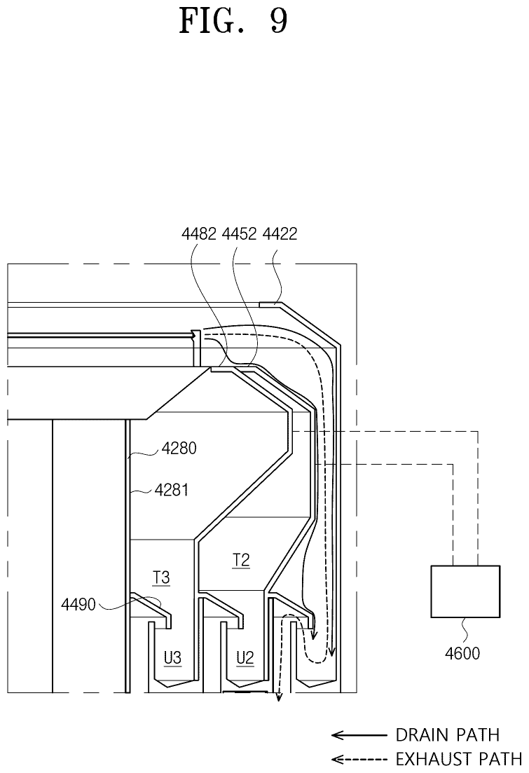

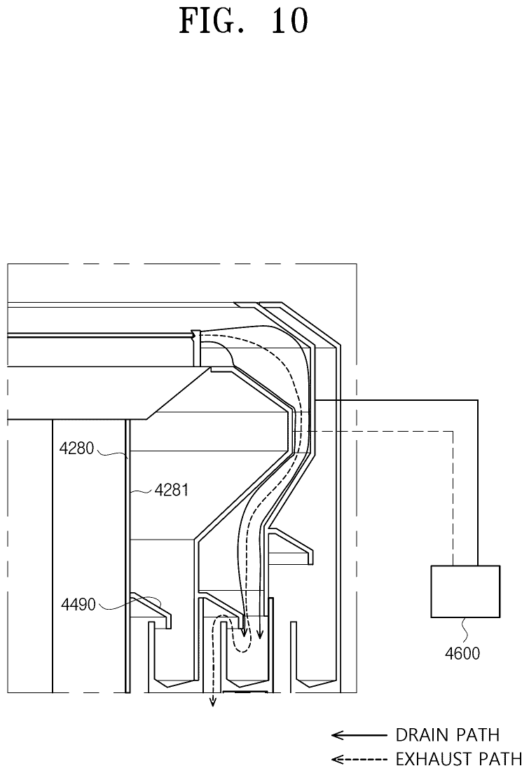

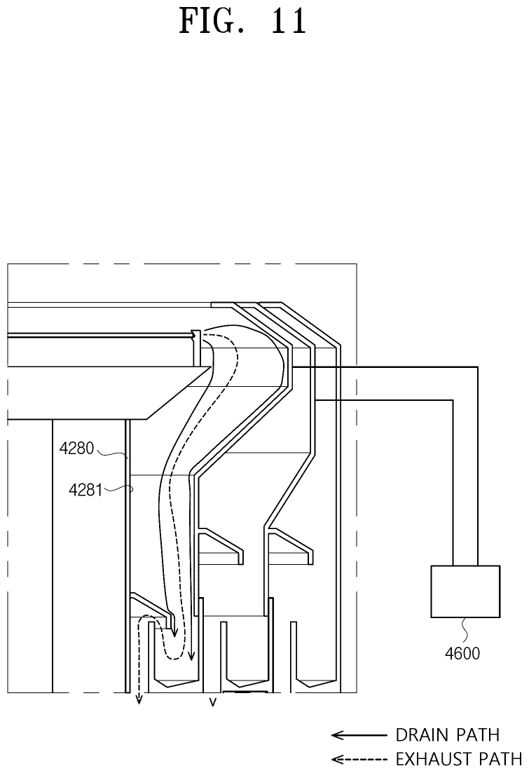

FIG. 8 is a view showing that guide plates have been provided in a buffer space when seen from above. The guide plates 4511, 4441, and 4471 are provided in the buffer spaces B1, B2, and B3. The guide plates 4511, 4441, and 4471 may be positioned higher than the exhaust pipes 4520, 4550, and 4580. The guide plates 4511, 4441, and 4471 may be provided in an arc shape. The widths of the guide plates 4511, 4441, and 4471 at the joints V1, V2, and V3 may be the same as the widths of the exhaust baths 4510, 4440, and 4470. Further, the widths of the guide plates 4511, 4441, and 4471 may decrease as they go away from the joints V1, V2, and V3. According to an example, the widths of the guide plates 4511, 4441, and 4471 may decrease while forming steps. Accordingly, the exhaust baths 4510, 4440, and 4470 may be composed of a first area A1 in which the widths of the guide plates 4511, 4441, and 4471 and the widths of the exhaust baths 4510, 4440, and 4470 are the same, a second area A2 in which the widths of the guide plates 4511, 4441, and 4471 are smaller than the widths of the exhaust baths 4510, 4440, and 4470, and a third area A3 in which the guide plates 4511, 4441, and 4471 are not provided.

The elevation unit 4600 moves the second guide cup 4450 and the third guide cup 4480 in the up-down direction. The relative height between the second guide cup 4450 and third guide cup 4480 and a substrate W is changed by up-down movement of the second guide cup 4450 and the third guide cup 4480. Accordingly, the exhaust baths 4510, 4440, and 4470 that recover treatment liquids are changed, depending on the kinds of treatment liquids that are supplied to substrates W, so it is possible to separately recover treatment liquids.

FIG. ##to FIG. ##are views showing that a treatment liquid is separately recovered by the elevation unit moving up the guide cups. Referring to FIG. #, when a substrate W is treated with a first treatment liquid, the elevation unit 4600 does not move up the second guide cup 4450 and the third guide cup 4480. Accordingly, when the first treatment liquid is splashed from the substrate W, the first treatment liquid is recovered to the first drain bath 4410 along the inner surface 4421a of the first guide cup, the third upper wall 4482, the second upper wall 4452, and the first gas-liquid separator plate 4430. A gas produced in this case is exhausted to an exhaust pipe through the first passage T1, the first connection channel V1, and the first buffer space B1. Referring to FIG. ##, when a substrate is treated with a second treatment liquid, the elevation unit moves up the second guide cup 4450. Accordingly, when the second treatment liquid is splayed from the substrate W, the second treatment liquid is recovered to the second drain bath 4440 along the inner surface 4451a of the second guide cup and the third upper wall 4482. A gas produced in this case is exhausted to an exhaust pipe through the second passage T2, the second connection channel V2, and the second buffer space B2. Referring to FIG. ###, when a substrate is treated with a third treatment liquid, the elevation unit moves up the second guide cup 4450 and the third guide cup 4480. Accordingly, when the third treatment liquid is splayed from the substrate W, the third treatment liquid is recovered to the third drain bath 4440 along the inner surface 4481a of the third guide cup. A gas produced in this case is exhausted to an exhaust pipe through the third passage T3, the third connection channel V3, and the third buffer space B3.

According to an embodiment of the present invention, even in a process in which a plurality of kinds of treatment liquids is provided, it is possible to separately recover not only the treatment liquids, but gases that are produced in the treatment process. The separately recovered gases can be recycled or can be separately discharged in accordance with regulations.

Further, when ring-shaped drain baths 4410, 4440, and 4470 are provided, the farter from the joints V1, V2, and V3 at which the exhaust pipes are connected, the lower the exhaust efficiency, so the pressures in the buffer spaces B1, B2, and B3 may not be uniform. When pressures are not uniform, exhaust by the exhaust baths 4510, 4440, and 4470 may not be efficiently performed. However, according to an embodiment of the present invention, since the guide plates 4511, 4441, and 4471 are provided, the pressures in the buffer spaces B1, B2, and B3 may be uniform.

It was exemplified in the above example that the widths of the guide plates 4511, 4441, and 4471 decrease while forming steps. However, the present invention is not limited thereto and the widths of the guide plates 4511, 4441, and 4471 may linearly decrease.

It was exemplified in the above example that the inner surfaces are flat surfaces. However, the present invention is not limited thereto, and as shown in FIG. ##, the inner surfaces may be concave surfaces.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

What is claimed is:

1. An apparatus of processing a substrate, comprising:
a cup unit having a treatment space therein;
a supporting unit supporting and rotating a substrate in the treatment space;
a liquid supply unit provided to supply a treatment liquid selected from a plurality of treatment liquids to a substrate supported on the supporting unit; and
an exhaust unit exhausting the treatment space,
wherein the cup unit comprises:
a first drain bath provided to surround an actuating shaft of the supporting unit and having a first recovery space to which a treatment is recovered;
a first drain pipe coupled to the first drain bath to discharge the treatment liquid recovered in the first recovery space;
a second drain bath provided to surround the first drain bath and having a second recovery space to which a treatment is recovered;
a second drain pipe coupled to the second drain bath to discharge the treatment liquid recovered in the second recovery space;
a first guide cup having a first inner surface guiding a treatment liquid, which is splashed from a substrate supported on the supporting unit, to the first drain bath; and
a second guide cup provided to be surrounded by the first guide cup and having a second inner surface guiding a treatment liquid, which is splashed from a substrate supported on the supporting unit, to the second drain bath,
wherein the exhaust unit comprises:
a first exhaust bath disposed under the cup unit and having a first buffer space into which airflow flowing through a first passage, which is provided between an inner surface of the first guide cup and an outer surface of the second guide cup, flows;
a first exhaust pipe connected to the first drain bath to discharge the airflow flowing in the first buffer space;
a second exhaust bath disposed under the cup unit and having a second buffer space into which airflow flowing through a second passage, which is provided to be surrounded by the first exhaust bath when seen from above and is provided inside the second guide cup, flows; and
a second exhaust pipe connected to the second exhaust bath to discharge the airflow flowing in the second buffer space, and
wherein a first connection channel connecting the first passage and the first buffer space is positioned between the first drain bath and the second drain bath, and
a second connection channel connecting the second passage and the second buffer space is positioned inside the second drain bath.

2. The apparatus of claim 1, wherein the first connection channel is provided as a ring-shaped slit surrounding the actuating shaft of the supporting unit or is provided as a plurality of holes arranged to form a ring shape when seen from above.

3. The apparatus of claim 1, wherein an arc-shaped guide plate is provided in the first buffer space,
the guide plate is positioned higher than a height at which the first exhaust pipe is connected to the first exhaust bath, and
the first exhaust pipe is connected to the first exhaust bath in an area covered by the guide plate when seen from above.

4. The apparatus of claim 3, wherein the first exhaust pipe is connected to the first exhaust bath at the center of the area covered by the guide plate when seen from above.

5. The apparatus of claim 4, wherein the farther from the point at which the first exhaust pipe is connected to the first exhaust bath, the smaller the width of the guide plate when seen from above.

6. The apparatus of claim 5, wherein a radial width of the first drain bath is constant in a longitudinal direction of the first drain bath when seen from above, and
the width of the guide plate is the same as the width of the first drain bath at the point at which the first exhaust pipe is connected to the first exhaust bath when seen from above.

7. The apparatus of claim 1, wherein the second exhaust bath is provided lower than the first exhaust bath.

8. The apparatus of claim 7, wherein a line connecting the point at which the first exhaust pipe is connected to the first exhaust bath and the actuating shaft of the driving unit and a line connecting a point at which the second exhaust pipe is connected to the second exhaust bath and the actuating shaft of the driving unit are provided not to overlap when seen from above.

9. The apparatus of claim 1, further comprising
an elevation unit adjusting a relative height between the first guide cup and the second guide cup.

10. The apparatus of claim 9, wherein when the first guide cup or the second guide cup is moved up, an outer wall of the first drain bath or an outer wall of the second drain bath extends farther than an inner wall of the first drain bath or an inner wall of the second drain bath such that a lower end of the first guide cup or the second guide cup is maintained in contact with the outer wall of the first drain bath or the outer wall of the second drain bath.

11. The apparatus of claim 1, further comprising a gas-liquid separator plate protruding from an outer surface of the second guide cup,
wherein the outer surface of the second guide cup is positioned inside further than an inner wall of the first drain bath when seen from above, and
the gas-liquid separator plate extends downward into the first recovery space and is spaced apart from the inner wall of the first drain bath.

12. The apparatus of claim 1, wherein the cup unit further comprises a third guide cup provided to be surrounded by the second guide cup, and
the second passage is formed between an inner surface of the second guide cup and an outer surface of the third guide cup.

13. An apparatus of processing a substrate, comprising:
a cup unit having a treatment space therein;
a supporting unit supporting and rotating a substrate in the treatment space;
a liquid supply unit provided to supply a treatment liquid selected from a plurality of treatment liquids to a substrate supported on the supporting unit; and
an exhaust unit exhausting the treatment space,
wherein the cup unit comprises:
a recovery bath recovering the treatment liquid; and
a guide cup guiding the treatment liquid to the recovery bath,
the recovery bath provides a recovery space,
a passage through which gas is exhausted is formed further inside than the recovery bath,
the exhaust unit comprises an exhaust bath disposed under the cup unit and provided in a ring shape along the passage, and an exhaust pipe connected to the exhaust bath,
the exhaust bath has a buffer space therein, and
an arc-shaped guide plate is provided in the buffer space.

14. The apparatus of claim 13, wherein the guide plate is positioned higher than a height at which the exhaust pipe is connected to the exhaust bath, and
the exhaust pipe is connected to the exhaust bath in an area covered by the guide plate when seen from above.

15. The apparatus of claim 14, wherein the exhaust pipe is connected to the exhaust bath at a center of the area covered by the guide plate when seen from above.

16. The apparatus of claim 15, wherein the farther from the point at which the first exhaust pipe is connected to the first exhaust bath, the smaller the width of the guide plate when seen from above.

17. The apparatus of claim 14, wherein a radial width of the drain bath is constant in a longitudinal direction of the drain bath when seen from above, and
the width of the guide plate is the same as the width of the drain bath at the point at which the exhaust pipe is connected to the exhaust bath when seen from above.

18. An apparatus of processing a substrate, comprising:
a cup unit having a treatment space therein;
a supporting unit supporting and rotating a substrate in the treatment space;
a liquid supply unit provided to supply a treatment liquid selected from a plurality of treatment liquids to a substrate supported on the supporting unit;
an elevation unit adjusting a relative height between the cup unit and the supporting unit; and
an exhaust unit exhausting the treatment space,
wherein the cup unit comprises:
a first drain bath provided to surround an actuating shaft of the supporting unit and having a first recovery space to which a treatment is recovered;
a first drain pipe coupled to the first drain bath to discharge the treatment liquid recovered in the first recovery space;
a second drain bath provided to surround the first drain bath and having a second recovery space to which a treatment is recovered;
a second drain pipe coupled to the second drain bath to discharge the treatment liquid recovered in the second recovery space;
a first guide cup having a first inner surface guiding a treatment liquid, which is splashed from a substrate supported on the supporting unit, to the first drain bath; and
a second guide cup provided to be surrounded by the first guide cup and having a second inner surface guiding a treatment liquid, which is splashed from a substrate supported on the supporting unit, to the second drain bath,
the elevation unit adjusts a relative height between the first guide cup and the second guide cup,
when the first guide cup or the second guide cup is moved up, an outer wall of the first drain bath or an outer wall of the second drain bath extends farther than an inner wall of the first drain bath or an inner wall of the second drain bath such that a lower end of the first guide cup or the second guide cup is maintained in contact with the outer wall of the first drain bath or the outer wall of the second drain bath,
the exhaust unit comprises:
a first exhaust bath disposed under the cup unit and having a first buffer space into which airflow flowing through a first passage, which is provided between an inner surface of the first guide cup and an outer surface of the second guide cup, flows;
a first exhaust pipe connected to the first drain bath to discharge the airflow flowing in the first buffer space;
a second exhaust bath disposed under the cup unit and having a second buffer space into which airflow flowing through a second passage, which is provided to be surrounded by the first exhaust bath when seen from above and is provided inside the second guide cup, flows; and
a second exhaust pipe connected to the second exhaust bath to discharge the airflow flowing in the second buffer space,
a first connection channel connecting the first passage and the first buffer space is positioned between the first drain bath and the second drain bath, and
a second connection channel connecting the second passage and the second buffer space is positioned inside the second drain bath,
an arc-shaped guide plate is provided in the first buffer space,
the first exhaust pipe is connected to the first exhaust bath at the center of the area covered by the guide plate when seen from above,
the guide plate is positioned higher than a height at which the first exhaust pipe is connected to the first exhaust bath, and
the farther from the point at which the first exhaust pipe is connected to the first exhaust bath, the smaller the width of the guide plate when seen from above.

19. The apparatus of claim 18, wherein a radial width of the first drain bath is constant in a longitudinal direction of the first drain bath when seen from above, and
the width of the guide plate is the same as the width of the first drain bath at the point at which the first exhaust pipe is connected to the first exhaust bath when seen from above.

20. The apparatus of claim 19, wherein the second exhaust bath is provided lower than the first exhaust bath, and
a line connecting the point at which the first exhaust pipe is connected to the first exhaust bath and the actuating shaft of the driving unit and a line connecting a point at which the second exhaust pipe is connected to the second exhaust bath and the actuating shaft of the driving unit are provided not to overlap when seen from above.
